(19) United States
(12) Patent Application Publication
(10) Pub. No.: US 2005/0264586 A1
(43) Pub. Date: Dec. 1, 2005

(54) Display device

(76) Inventor: Tae-Sung Kim, Suwon-si (KR)

Correspondence Address: F. CHAU & ASSOCIATES, LLC, 130 WOODBURY ROAD, WOODBURY, NY, 11797, US

(21) Appl. No.: 11/126,070

(22) Filed: May 10, 2005

(30) Foreign Application Priority Data
May 25, 2004 (KR) 2004-37416

(51) Int. Cl. H03M 9/00

(52) U.S. Cl. 345/690

(57) ABSTRACT

A display device is provided. The display device includes a signal controller for converting image data from an external device into multi-level signals, a data driver for receiving and converting the multi-level signals into analog data voltages corresponding thereto and for outputting the analog data voltages; and a panel assembly provided with a plurality of scanning signal lines, a plurality of data lines for transmitting the analog data voltages, and a plurality of pixels respectively connected to the scanning lines and the data lines for displaying the image data according to the analog data voltages received from the data lines.

### FIELD OF THE INVENTION

The present invention relates to a display device and, more particularly, to a signal transmission method for use with the display device.

### DESCRIPTION OF THE RELATED ART

Display devices typically include a plurality of pixels, a data driver for supplying data voltages thereto and a signal controller for processing and providing image data from an external device to the data driver. Display devices also require a number of transmission lines for transmitting the data from the signal controller to the data driver. These transmission lines tend to generate a large amount of electromagnetic interference (EMI).

To reduce the amount of EMI, differential driving schemes such as low voltage differential signaling (LVDS) and reduced swing differential signaling (RSDS) have been developed. Generally, LVDS is used when transmitting data from an external device to the display device and RSDS is used when transmitting data from the signal controller to the data driver positioned in the display device.

In another differential driving scheme, one signal is transmitted via two signal lines. In other words, two signals having the same magnitude but opposite polarities are transmitted from transmitting terminals and are recognized by the differences in their levels at receiving terminals located at both ends of the signal lines. Because the RSDS scheme lowers the signal levels relative to a single line transmission scheme, the magnitude of the electromagnetic field generated in each line is small and the EMI is minimized. This is done by canceling out the electromagnetic wave occurring between signals having opposite polarities. In addition, because the data is recognized by the difference between the two signals, even though noise is present in the signal lines, there is almost no loss of data.

Because this differential driving scheme requires two signal lines for each channel to duplicate the number of signal lines, in order to prevent this from happening, the scheme employs a method so that 2 bits of data are transmitted via one channel by using 2:1 multiplexing. Accordingly, the frequency is doubled but the number of the signal lines remains the same. However, because the maximum operating speed of currently available driving integrated circuits for display devices supporting RSDS is around, e.g., 85 MHz, a dual-channel structure for use with two parallel channels is employed when operating at high resolutions that require operating speeds or frequencies higher than, e.g., 75 Hz.

This dual-channel structure, however, increases the number of signal lines on a data printed circuit board (PCB), which connects the signal controller and the data driver, thus causing an increase in the size of the PCB. This further causes the arrangement of the signal lines thereon to be complex. In addition, the number of layers and the cost to manufacture the PCB increases as well. Moreover, when parallel driving, the number of pins required for driving is doubled because the signal controller inputs the signals to two buses at the same time. This further results in an increase in the size and cost of the chip package of the signal controller.

### SUMMARY OF THE INVENTION

In accordance with an exemplary embodiment of the present invention, a display device comprises: a signal controller for converting image data from an external device into multi-level signals; a data driver for receiving and converting the multi-level signals into corresponding analog data voltages and for outputting the analog data voltages; and a panel assembly comprising a plurality of scanning signal lines, a plurality of data lines for transmitting the analog data voltages, and a plurality of pixels connected to the scanning lines and the data lines for displaying the image data according to the analog data voltages received from the data lines.

The multi-level signals are transmitted in a differential signal transmission scheme. The differential signal transmission scheme is a reduced swing differential signaling (RSDS) scheme.

When the image data is binary coded the signal controller comprises: a first data processor for converting the binary coded image data into gray coded data; and a data transmitter for converting the gray coded data into the multi-level signals for transmitting. The data transmitter comprises: a modulator for converting the gray coded data into thermometer coded data; and a transmitting stage for transmitting multi-level signals corresponding to the thermometer coded data.

The data driver comprises: a data receiver for receiving the multi-level signals and for converting the multi-level signals into the gray coded data; and a second data processor for converting the gray coded data into the binary coded data and for converting the binary coded data into the analog data voltages applied to the data lines. The data receiver comprises: a receiving stage for receiving the multi-level signals and for converting the multi-level signals into the thermometer coded data; and a demodulator for converting the thermometer coded data into the gray coded data.

The receiving stage comprises: a plurality of comparators, each having a first terminal applied to one of the multi-level signals, a second terminal connected to a reference voltage and a third terminal connected to the demodulator, wherein the second terminals are connected to the reference voltages having different reference values.

The transmitting stage comprises: a resistor connected between a first voltage and an output terminal; a plurality of current sources connected in parallel to the resistor; and a plurality of switching elements, each having a first terminal connected to the modulator and a second terminal connected to the current source and a third terminal connected to a second voltage. The switching elements are negative-channel metal oxide semiconductor (NMOS) type transistors.

The transmitting stage comprises: a transistor connected between a first voltage and an output terminal; a plurality of current sources connected in parallel to the transistor; and a plurality of switching elements, each having a first terminal connected to the modulator and a second terminal connected to the current source and a third terminal connected to a second voltage. The transistor is a positive-channel metal oxide semiconductor (PMOS) type transistor. The multi-level signals have at least four levels.

In accordance with another exemplary embodiment of the present invention, a method for display image data comprises: converting, at a signal controller, image data from an external device into multi-level signals; receiving and converting, at a data driver, the multi-level signals into corresponding analog data voltages and outputting the analog data voltages; and displaying, at a panel assembly, the image data according to the analog data voltages. The multi-level signals are transmitted in a differential transmission scheme.

The image data is binary coded and the method further comprises: converting, at a first data processor of the signal controller, the binary coded image data into gray coded data; and converting, at a data transmitter of the signal controller, the gray coded data in the multi-level signals for transmission. The method further comprises: converting, at a modulator of the data transmitter, the gray coded data into thermometer data; and transmitting, at a transmitting stage of the data transmitter, multi-level signals corresponding to the thermometer coded data.

The method further comprises: receiving, at a data receiver of the data driver, the multi-level signals for converting the multi-level signals into the gray coded data; and converting, at a second data processor of the data driver, the gray coded data into the binary coded data for converting the binary coded data into the analog data voltages. The method further comprises: receiving, at a receiving stage of the data receiver, the multi-level signals; converting, at the receiving stage of the data receiver, the multi-level signals into the thermometer coded data; and converting, at a demodulator of the data receiver, the thermometer coded data into the gray coded data. The multi-level signals have at least four levels.

### BRIEF DESCRIPTION OF THE DRAWINGS

The above and other features of the present invention will become more apparent by describing in detail exemplary embodiments thereof with reference to the accompanying drawings in which:

FIG. 1 is a block diagram of a display device according to an exemplary embodiment of the present invention;

FIG. 2 is an equivalent circuit diagram of a pixel of a liquid crystal display (LCD) according to an exemplary embodiment of the present invention;

FIG. 3 is a schematic view of a display device according to an exemplary embodiment of the present invention;

FIG. 4 is a schematic block diagram of a signal controller and a data driver according to an exemplary embodiment of the present invention;

FIG. 5 is a schematic view of a signal transmission stage and a signal receiving stage according to an exemplary embodiment of the present invention;

FIG. 6 is a circuit diagram of a 4-level signal transmission stage according to an exemplary embodiment of the present invention;

FIG. 7 is a circuit diagram of a 4-level signal receiving stage according to an exemplary embodiment of the present invention;

FIG. 8 is a waveform of a 4-level signal according to an exemplary embodiment of the present invention; and

FIG. 9 illustrates waveforms of a conventional reduced swing differential signaling (RSDS) signal and 4-level RSDS signal according to an exemplary embodiment of the present invention.

### DETAILED DESCRIPTION OF EXEMPLARY EMBODIMENTS

The present invention will now will be described more fully hereinafter with reference to the accompanying drawings, in which exemplary embodiments of the invention are shown. This invention may, however, be embodied in many different forms and should not be construed as limited to the embodiments set forth herein.

In the drawings, the thickness of layers and regions are exaggerated for clarity. Like numerals refer to like elements throughout. It will be understood that when an element such as a layer, film, region, substrate or panel is referred to as being “on” another element, it can be directly on the other element or intervening elements may also be present. In contrast, when an element is referred to as being “directly on” another element, there are no intervening elements present.

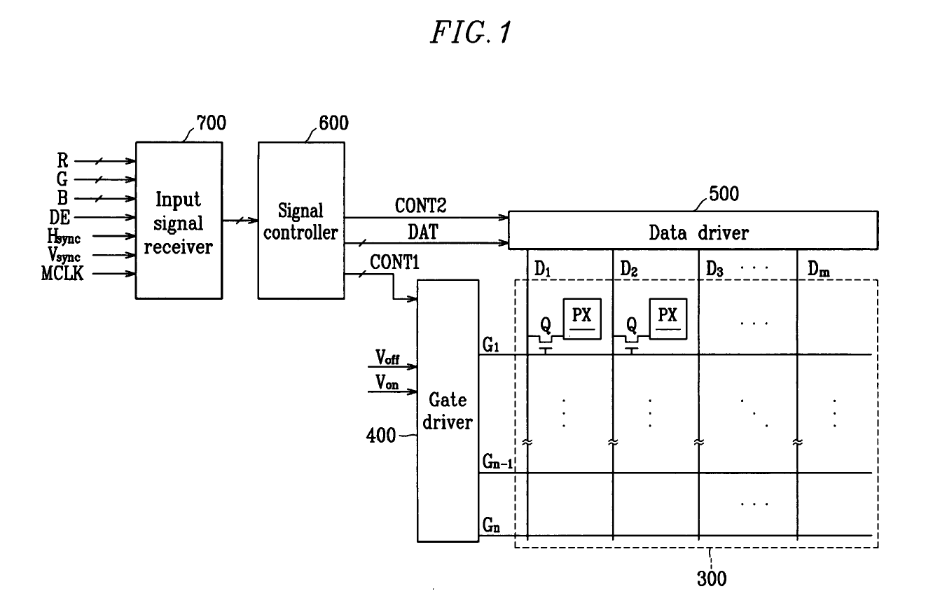

A display device according to an exemplary embodiment of the present invention will now be described with reference to FIGS. 1 to 3.

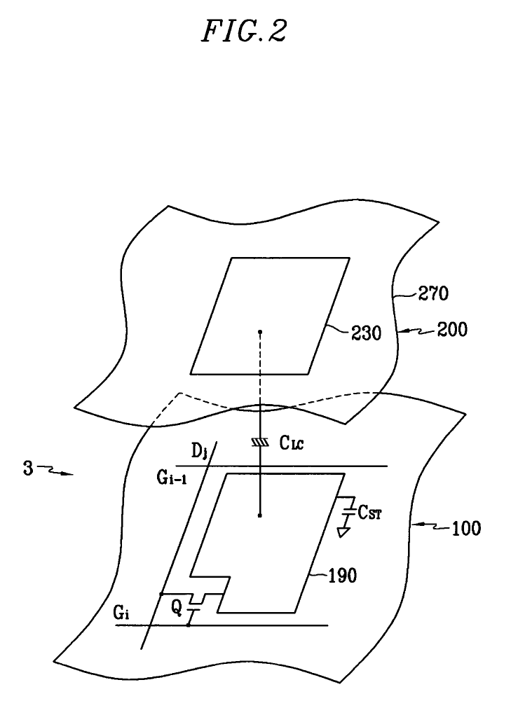

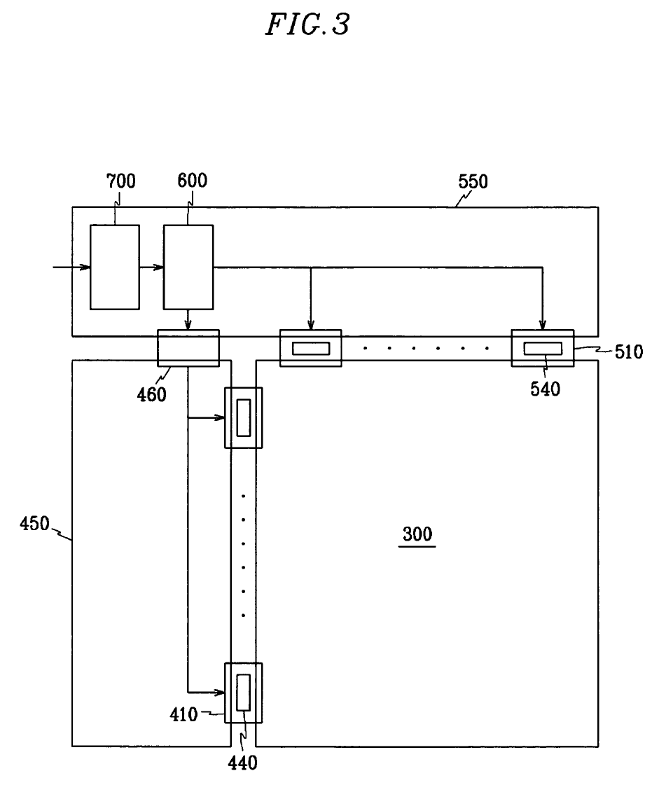

FIG. 1 is a block diagram of a display device according to an exemplary embodiment of the present invention, FIG. 2 is an equivalent circuit diagram of a pixel of a liquid crystal display (LCD) according to an exemplary embodiment of the present invention, and FIG. 3 is a schematic view of a display device according to an exemplary embodiment of the present invention.

Referring to FIG. 1, the display device includes a panel assembly 300, a gate driver 400 and a data driver 500 connected thereto, and a signal controller 600 for controlling the panel assembly 300, gate driver 400 and data driver 500.

The panel assembly 300 includes a plurality of display signal lines G1-Gn and D1-Dm and a plurality of pixels connected thereto arranged in a matrix.

The display signal lines G1-Gn and D1-Dm are provided on a lower panel 100 (shown in FIG. 2) and include a plurality of gate lines G1-Gn for transmitting gate signals (e.g., scanning signals) and a plurality of data lines D1-Dm for transmitting data signals. The gate lines G1-Gn extend in a row direction and are parallel to each other, while the data lines D1-Dm extend in a column direction and are parallel to each other.

Each pixel includes a switching element Q connected to the display signal lines G1-Gn and D1-Dm, and pixel circuits PX connected to the switching elements Q.

The switching element Q is provided on the lower panel 100 and has three terminals: a control terminal connected to one of the gate lines G1-Gn; an input terminal connected to one of the data lines D1-Dm; and an output terminal connected to the pixel circuit PX.

In an active matrix type LCD, which is a representative display device, the panel assembly 300 includes the lower panel 100, an upper panel 200 (shown in FIG. 2) and a liquid crystal layer 3 (also shown in FIG. 2) interposed therebetween, with the display signal lines G1-Gn and D1-Dm and the switching elements Q provided on the lower panel 100. Each pixel circuit PX includes an inductor/capacitor (LC) capacitor C_{LC} and a storage capacitor C_{ST} in parallel and connected to the switching element Q. The storage capacitor C_{ST} may be omitted if unnecessary.

The LC capacitor C_{LC} includes a pixel electrode 190 on the lower panel 100, and a common electrode 270 on the upper panel 200 with the liquid crystal layer 3 acting as a dielectric between the electrodes 190 and 270. The pixel electrode 190 is connected to the switching element Q, and the common electrode 270 covers the entire surface of the upper panel 100 and is supplied with a common voltage Vcom. Alternatively, both the pixel electrode 190 and the common electrode 270, which have shapes of bars or stripes, are provided on the lower panel 100.

The storage capacitor C_{ST} is an auxiliary capacitor for the LC capacitor C_{LC}. The storage capacitor C_{ST} includes the pixel electrode 190 and a separate signal line (not shown), which is provided on the lower panel 100, overlaps the pixel electrode 190 via an insulator, and is supplied with a predetermined voltage such as the common voltage Vcom. Alternatively, the storage capacitor C_{ST} includes the pixel electrode 190 and an adjacent gate line, for example, a previous gate line, which overlaps the pixel electrode 190 via an insulator.

For color display, each pixel uniquely represents one of the three primary colors such as red (R), green (G) and blue (B) (e.g., when using spatial division) or sequentially represents the three primary colors in time (e.g., when using temporal division), thereby obtaining a desired color. FIG. 2 shows an example in spatial division where each pixel includes a color filter 230 representing one of the three primary colors in an area of the upper panel 200 facing its pixel electrode 190. Alternatively, the color filter 230 is provided on or under the pixel electrode 190 on the lower panel 100.

A pair of polarizers (not shown) for polarizing light are attached to the outer surfaces of the panels 100 and 200 of the panel assembly 300.

The pixels may have different structures depending on the types of display devices used.

Referring back to FIG. 1, the gate driver 400 is connected to the gate lines G1-Gn of the panel assembly 300 and synthesizes a gate-on voltage Von and a gate off voltage Voff to generate gate signals for application to the gate lines G1-Gn.

The data driver 500, which is connected to the data lines D1-Dm of the panel assembly 300, applies data voltages selected from gray voltages that are supplied from a gray voltage generator (not shown) to the data lines D1-Dm.

The signal controller 600 receives a variety of signals including image data from an external device for controlling the gate driver 400 and the data driver 500.

Referring now to FIG. 3, a display device according to an exemplary embodiment of the present invention includes a panel assembly 300, a gate printed circuit board (PCB) 450, a data PCB 550, a plurality of gate tape carrier packages (TCPs) 410, a plurality of data TCPs 510 and a flexible printed circuit film (FPC) 460.

The gate TCPs 410 are attached to the panel assembly 300 and the gate PCB 450, the data TCPs 510 are attached to the panel assembly 300 and the data PCB 550, and the FPC 460 is attached to the gate PCB 450 and the data PCB 550.

The data PCB 550 is provided with an input signal receiver 700 and a signal controller 600, and the gate and the data TCPs 410 and 510 are provided with a plurality of gate driving integrated circuits (ICs) 440 comprising the gate driver 400 and a plurality of data driving ICs 540 comprising the data driver 500, respectively.

The PCBs 450 and 550, the TCPs 410 and 510 and the FPC 460 are provided with a plurality of signal lines (not shown) for signal transmission between the input signal receiver 700, the signal controller 600, the gate driving ICs 440 and the data driving ICs 540.

Unlike that shown in FIG. 3, the input signal receiver 700 and the signal controller 600 may be provided on the gate PCB 450.

At least one of the gate PCB 450 and the data PCB 550, in particular, the gate PCB 450 may be omitted, and in such a case the FPC 460 may be omitted and related signal lines may be provided on the panel assembly 300 and the gate TCP 410.

The gate driving ICs 440 and the data driving ICs 540 are mounted on the panel assembly 300 directly in a chip on glass (COG) fashion. Alternatively, the driving ICs 440 and 540, in particular, the gate driving ICs 440 are integrated into the panel assembly 300.

The operation of the display device will now be described in detail.

The input signal receiver 700 is supplied with input image data R, G and B, input control signals for controlling the display thereof such as a vertical synchronization signal Vsync, a horizontal synchronization signal Hsync, a main clock MCLK, and a data enable signal DE from an external graphic controller (not shown). The input image data R, G and B and the input control signals, which the input signal receiver 700 converts into a binary digital signal of 1 bit for each channel for output to the signal controller 600, may be transmitted in a differential signal transmission scheme such as a low voltage differential signaling (LVDS) scheme and a reduced swing differential signaling (RSDS) scheme.

After generating gate control signals CONT1 and data control signals CONT2 and processing the image data R, G and B suitable for the operation of and transmission to the panel assembly 300 on the basis of the input control signals, the signal controller 600 provides the gate control signals CONT1 to the gate driver 400, and the processed image signals DAT and the data control signals CONT2 to the data driver 500. In this case, the image signals DAT are analog signals with a plurality of discrete values and the gate control signals CONT1 and the data control signals CONT2 are digital signals. However, the control signals CONT1 and CONT2 may be analog signals with a plurality of discrete values.

The gate control signals CONT1 include a vertical synchronization start signal STV for indicating the start of scanning, a gate clock signal CPV for controlling the output time of a scanning signal, and an output enable signal OE for defining the width of the scanning signal.

The data control signals CONT2 include a horizontal synchronization start signal STH for indicating the start of transmission of the image signals DAT, a load signal LOAD for instructing the appropriate data voltages to be applied to the data lines D1-Dm, and a data clock signal HCLK. In an LCD as shown in FIG. 2, the data control signals CONT2 may include an inversion control signal RVS for reversing the polarity of the data voltages with respect to the common voltage Vcom.

The data driver 500 receives a packet of the image data DAT, which is multi-leveled, for a pixel row from the signal controller 600 and converts the image data DAT into binary digital data and then into analog data voltages in response to the data control signals CONT2 from the signal controller 600, and then applies the analog data voltages to the data lines D1-Dm.

In response to the gate control signals CONT1 from the signal controller 600, the gate driver 400 applies the scanning signal to the gate lines G1-Gn, thereby turning on the switching elements Q connected thereto. Then, the data voltages applied to the data lines D1-Dm are supplied to corresponding pixels via the turned-on switching elements Q.

In the LCD shown in FIG. 2, the difference between the data voltage and the common voltage Vcom applied to a pixel is expressed as a charged voltage of the LC capacitor C_{LC}, e.g., a pixel voltage. As the liquid crystal molecules have orientations depending on the magnitude of the pixel voltage the orientations determine the polarization of light passing through the LC capacitor C_{LC}. The polarizers convert the polarization of light into the transmitted light.

The data driver 500 applies the data voltages to the corresponding data lines D1-Dm for a turn-on time of the switching elements Q. The turn-on time of the switching elements Q is, for example, one horizontal period or 1H, and is equal to one period of each of the horizontal synchronization signal Hsync, the data enable signal DE, and the gate clock signal CPV.

By repeating this procedure, the gate lines G1-Gn are sequentially supplied with the scanning signal during a frame, thereby applying the data voltages to all pixels. In the LCD shown in FIG. 2, when the next frame starts after finishing one frame, the inversion control signal RVS applied to the data driver 500 is controlled such that the polarity of the data voltages is reversed (e.g., a frame inversion takes place). The inversion control signal RVS may also be controlled such that the polarity of the data voltages flowing in a data line in one frame are reversed (e.g., a line inversion or dot inversion takes place), or the polarity of the data voltages in one packet are reversed (e.g., a column inversion or dot inversion takes place).

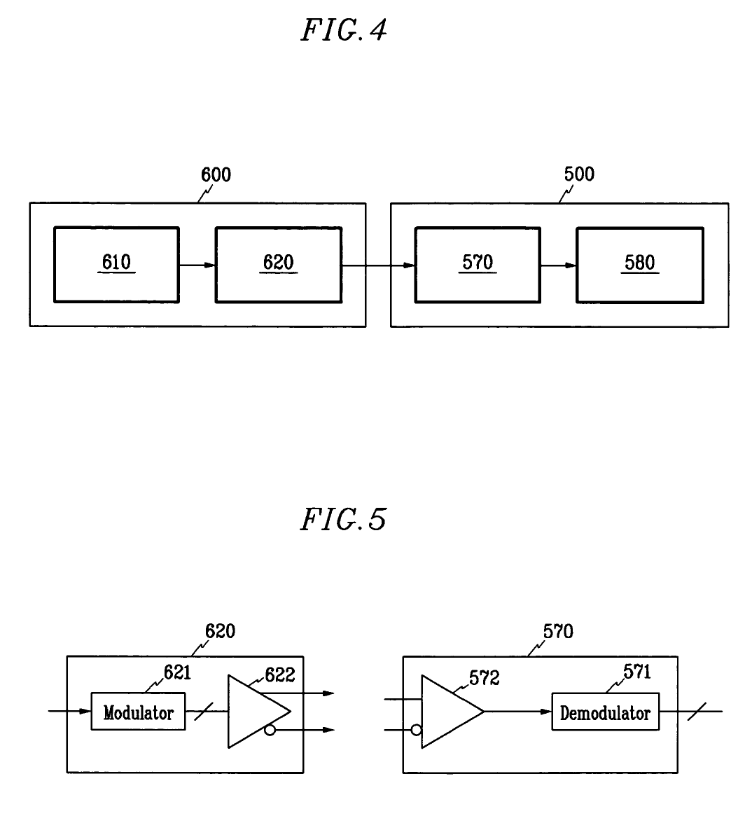

Now, signal transmission and receipt by a signal controller and a data driver of a display device according to an exemplary embodiment of the present invention will be described more in detail with reference to FIGS. 4 and 5.

FIG. 4 is a block diagram illustrating a portion of the signal controller 600 and the data driver 500 of the display device according to an exemplary embodiment of the present invention, and FIG. 5 is a block diagram of a data transmitter of the signal controller 600 and a data receiver of the data driver 500 according to an exemplary embodiment of the present invention.

As shown in FIGS. 4 and 5, the signal controller 600 includes a data processor 610 connected the input signal receiver 700 and a data transmitter 620 connected thereto. The data transmitter 620 includes a modulator 621 connected to the data processor 610 and a multi-level signal transmitting stage 622 connected thereto. The data driver 500 includes a data receiver 570 connected to the data transmitter 620 of the signal controller 600 and a data processor 580 connected to the data receiver 570 and the panel assembly 300. The data receiver 570 includes a multi-level receiver 572 connected to the multi-level transmitter 622 and a demodulator 571 connected thereto. In this case, the data transmitter 620 may be implemented in an apparatus separate from the signal controller 600.

The data processor 610 of the signal controller 600 processes binary digital data from the input signal receiver 700 suitable for the characteristics of the panel assembly 300 and provides the processed data to the modulator 621 of the data transmitter 620. For example, the data processor 610 converts the image data of a binary code, e.g., 1-bit of 0 and 1 into gray code.

The gray code is formed by inserting one more middle levels between 0 and 1. This is used when transmitting a large amount of data. For example, when two levels are inserted between the binary code of 0 and 1, four different levels exist therein, which are allocated to 2 bits.

Furthermore, when the gray code is 2 bits such as 00, 01, 11 and 10, two adjacent levels have only one bit different from each other. Use of such a coding system where two adjacent levels are different by only one bit reduces the occurrence of errors. This is because even though 1 bit is changed, such as 0 to 1 or 1 to 0 due to interference, etc., the maximum two levels, e.g., the maximum 1 bit, are different from the original data.

The modulator 621 modulates the gray code into a thermometer code.

The thermometer code is a coding system where corresponding levels are discriminated by the number of consecutive is, for example, the binary code of 4 bits corresponding to the decimal number 0, 1, 2, 3, 4, . . . are represented as 0000, 0001, 0010, 0011, . . . respectively, while the thermometer codes corresponding thereto are represented as 0000000000000001, 0000000000000011, 0000000000000111, 0000000000001111, and so on. For example, when an error datum is 0000000000001011 in the thermometer code, an original datum is either 000000000000001 or 000000000000111 and the difference between the two values is only 2 in the decimal number. However, when an error datum is 1011 in binary, the difference increases depending on which bits have errors in the decimal number. For example, when the leftmost bit has an error, an original datum is 0011, and when the rightmost bit has an error, an original datum is 1010, thereby the difference between the 0011 and 1010 datum is large. Therefore, a thermometer code reduces the occurrence of data errors similar to that of the gray code.

The multi-level signal transmitting stage 622 receives the thermometer-coded data of p-bits from the modulator 621 and converts them into analog signals with different p discrete values, e.g., multi-level values.

The data receiver 570 of the data driver 500 operates in a reverse order relative to the data transmitter 620 of the signal controller 600. In more detail, the multi-level signal receiving stage 572 receives analog signals with multi-level values having a number of, e.g., p, from the data transmitter 620 and converts and outputs them into thermometer coded data of p bits. The demodulator 571 converts the p-bit thermometer coded data into the original gray coded data.

After converting the gray coded data into the binary coded data for converting into analog data, the data processor 580 of the data driver 500 applies the analog data to the data lines D1-Dm.

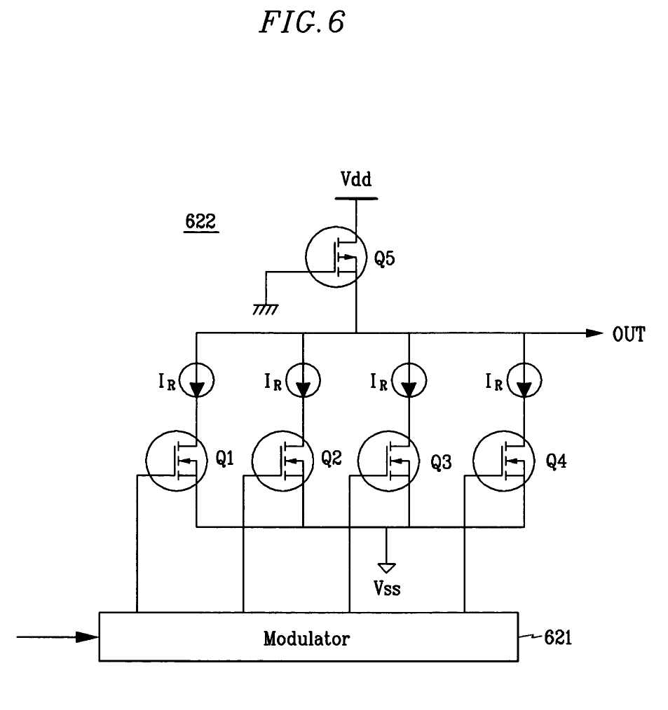

A multi-level signal transmitting stage and receiver will now be described with reference to FIGS. 6 to 8 in detail.

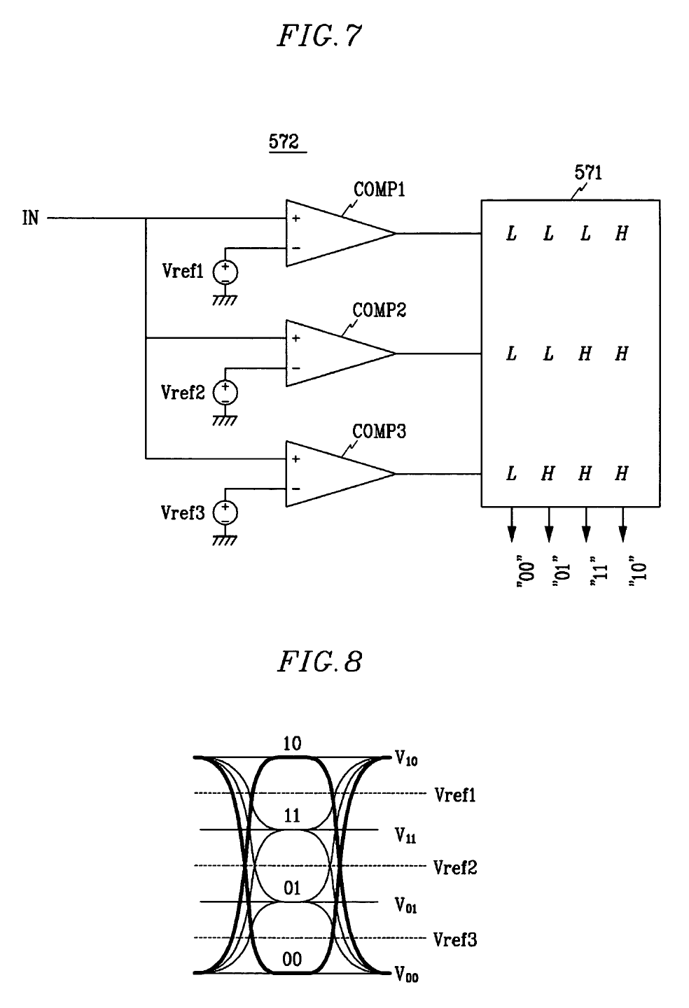

FIG. 6 is a circuit diagram of 4-level signal transmitting stage according to an exemplary embodiment of the present invention, FIG. 7 is a circuit diagram of 4-level signal receiving stage according to an exemplary embodiment of the present invention, and FIG. 8 is a waveform of a 4-level signal according to an exemplary embodiment of the present invention. The 4-level signal transmitting stage and receiver shown in FIGS. 6 and 7 illustrate the case where p is 4 in the example described above.

As shown in FIG. 6, the 4-level transmitting stage 622 includes four negative-channel metal oxide semiconductor (NMOS) transistors Q1 to Q4 connected in parallel to the modulator 621 with current sources IR connected thereto, and a positive-channel metal oxide semiconductor (PMOS) transistor Q5 connected commonly to the current sources I_{R}. In more detail, the gates of the NMOS transistors Q1 to Q4 are connected to the modulator 621, the sources thereof are connected to a predetermined low voltage Vss and the drains thereof are connected to the current sources I_{R}. The gate of the PMOS transistor Q5 is connected to a ground voltage, the source thereof to the current sources I_{R} and the drain thereof to a predetermined high voltage Vdd. The PMOS transistor Q5 is always turned on to function as a load and may be substituted with a resistor.

Now, operations of the modulator 621 and the 4-level signal transmitting stage 622 will be described in detail.

In operation, the modulator 621 converts gray coded data of 2 bits into thermometer data of 4 bits, for example, by converting (00) into (1111), (01) into (0111), (11) into (0011) and (10) into (0001).

The transmitting stage 622 transmits multi-level signals having voltage levels corresponding to the thermometer codes. In more detail, each transistor Q1 to Q4 is tuned off when the output of the modulator 621 is at a low level, e.g., 0, and turned on when at a high level, e.g., 1, thereby pulling down the output voltages. Accordingly, as the number of 1 is more in the output of the 4-level signal transmitting stage 621, the number of transistors Q1 to Q4 used for pulling-down the output voltages increases in proportion thereto, and thereby the level of the output voltages is reduced. For example, when the bits of the output of the modulator are 0, the transistors Q1 to Q4 are turned off and not connected to the ground voltage, thereby the output voltage becomes the high voltage Vdd.

When any one of the output bits of the modulator 621 is 1, one of the transistors Q1 to Q4 is turned on and then the current I_{R} flows to drop the voltage. When two of the output bits are 1, two of the transistors Q1 to Q4 are turned on such that a total current is double that as compared to when one output bit is 1, thus dropping the voltage by that degree. In this way, the total current depends on the number of the turned-on transistors Q1 to Q4, and according thereto the levels of the output voltages are varied. Therefore, a multi-level signal OUT, e.g., a 4-level signal with four levels V00, V01, V11 and V10 corresponding to the thermometer codes is formed.

As shown in FIG. 7, the receiving stage 572 includes three comparators COMP1 to COMP3 with their non-inverting inputs being outputs of the transmitting stage 622. The three comparators COMP1 to COMP3 have their inverting inputs connected to predetermined reference voltages Vref1 to Vref3, respectively. The three reference voltages Vref1 to Vref3 are for discrimination of the four levels of the voltages, and, as shown in FIGS. 7 and 8, the comparators COMP1(i=1, 2, 3) seek and output higher and lower voltages than the reference voltages Vrefi, which are thermometer codes.

The demodulator 571 reconverts the outputs of the comparators COMP1 to COMP3 into gray coded data for output to the data processor 580 of the data driver 500.

In order to transmit the multi-level signals with voltage levels of p, the modulator 621 generates a thermometer code of p bits when the number of NMOS transistors in the data transmitter 620 is p, the number of the comparators in the receiver 572 is (p−1), and the demodulator 571 converts the outputs of the receiver 572 into the gray coded data.

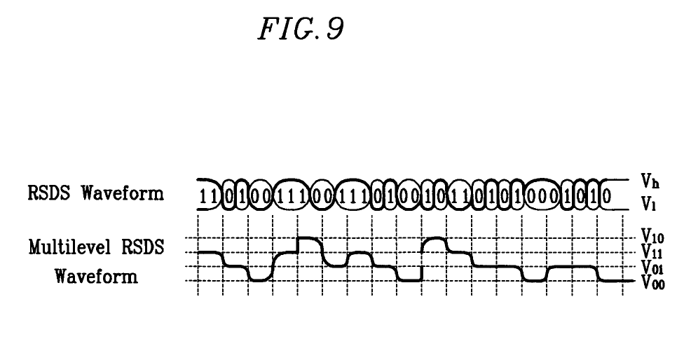

FIG. 9 illustrates waveforms of a conventional RSDS signal and 4-level RSDS signal according to an exemplary embodiment of the present invention.

As shown in FIG. 9, because the signal according to present invention has 4 levels of V00 to V10 relative to the conventional signal having 2 levels such as 0 and 1, 2 bits of data are transmitted at the same time, and accordingly transmission efficiency doubles.

When using the same bus lines in a conventional RSDS scheme, because transmission frequency of the data decreases by half, more than double the transmission efficiency can occur in view of certain amounts of EMI or power being consumed. The maximum speed for transmitting data between the signal controller and the driving ICs is thus limited by the length of the channels and the transmission characteristics of the PCB. However, by using multi-level signals data can be transmitted at speeds that are more than double that transmitted via a single channel. Accordingly, in order to operate at high resolutions, a 2-channel RSDS is used in the conventional display device but only one channel is used in the display device according to the present invention when both devices are operating at the same speed.

Thus, the display device according to the present invention, decreases the amount of power being consumed and EMI even when not operating at high resolutions and as the number of the mid-level signals increases, the efficiency of the display device increases in proportion thereto. In addition, when transmitting data at the same frequency bandwidth, the number of transmission lines required for transmitting four data bits via the same channel decreases by half by increasing the number of mid-level signals.

Thus, data can be transmitted at speeds that are more than double when using the same number of bus lines, and the number of the bus lines can be decreased when transmitting data at the same speed. Because the techniques of the present invention reduce the size of the PCB by transmitting through a single channel and reduces the number of pins of the signal controller, inexpensive packaging can be used to reduce manufacturing costs.

While the present invention has been described in detail with reference to the exemplary embodiments, it is to be understood that the invention is not limited to the disclosed embodiments, but, on the contrary, is intended to cover various modifications and equivalent arrangements included within the sprit and scope of the appended claims.

1. A display device comprising:
a signal controller for converting image data from an external device into multi-level signals;
a data driver for receiving and converting the multi-level signals into corresponding analog data voltages and for outputting the analog data voltages; and
a panel assembly comprising a plurality of scanning signal lines, a plurality of data lines for transmitting the analog data voltages, and a plurality of pixels connected to the scanning lines and the data lines for displaying the image data according to the analog data voltages received from the data lines.

2. The display device of claim 1, wherein the multi-level signals are transmitted in a differential signal transmission scheme.

3. The display device of claim 2, wherein the differential signal transmission scheme is a reduced swing differential signaling (RSDS) scheme.

4. The display device of claim 1, wherein the image data is binary coded, wherein the signal controller comprises:
a first data processor for converting the binary coded image data into gray coded data; and
a data transmitter for converting the gray coded data into the multi-level signals for transmitting.

5. The display device of claim 4, wherein the data transmitter comprises:
a modulator for converting the gray coded data into thermometer coded data; and
a transmitting stage for transmitting multi-level signals corresponding to the thermometer coded data.

6. The display device of claim 5, wherein the data driver comprises:
a data receiver for receiving the multi-level signals and for converting the multi-level signals into the gray coded data; and
a second data processor for converting the gray coded data into the binary coded data and for converting the binary coded data into the analog data voltages applied to the data lines.

7. The display device of claim 6, wherein the data receiver comprises:
a receiving stage for receiving the multi-level signals and for converting the multi-level signals into the thermometer coded data; and
a demodulator for converting the thermometer coded data into the gray coded data.

8. The display device of claim 7, wherein the receiving stage comprises:
a plurality of comparators, each having a first terminal applied to one of the multi-level signals, a second terminal connected to a reference voltage and a third terminal connected to the demodulator, wherein the second terminals are connected to the reference voltages having different reference values.

9. The display device of claim 8, wherein the transmitting stage comprises:
a resistor connected between a first voltage and an output terminal;
a plurality of current sources connected in parallel to the resistor; and
a plurality of switching elements, each having a first terminal connected to the modulator and a second terminal connected to the current source and a third terminal connected to a second voltage.

10. The display device of claim 9, wherein the switching elements are negative-channel metal oxide semiconductor (NMOS) type transistors.

11. The display device of claim 8, wherein the transmitting stage comprises:
a transistor connected between a first voltage and an output terminal;
a plurality of current sources connected in parallel to the transistor; and
a plurality of switching elements, each having a first terminal connected to the modulator and a second terminal connected to the current source and a third terminal connected to a second voltage.

12. The display device of clam 11, wherein the transistor is a positive-channel metal oxide semiconductor (PMOS) type transistor.

13. The display device of claim 1, wherein the multi-level signal have at least four levels.

14. A method for display image data, comprising:
converting, at a signal controller, image data from an external device into multi-level signals;
receiving and converting, at a data driver, the multi-level signals into corresponding analog data voltages and outputting the analog data voltages; and
displaying, at a panel assembly, the image data according to the analog data voltages.

15. The method of claim 14, wherein the multi-level signals are transmitted in a differential transmission scheme.

16. The method of claim 14, wherein the image data is binary coded, further comprising:
converting, at a first data processor of the signal controller, the binary coded image data into gray coded data; and
converting, at a data transmitter of the signal controller, the gray coded data in the multi-level signals for transmission.

17. The method of claim 16, further comprising:
converting, at a modulator of the data transmitter, the gray coded data into thermometer data; and
transmitting, at a transmitting stage of the data transmitter, multi-level signals corresponding to the thermometer coded data.

18. The method of claim 17, further comprising:
receiving, at a data receiver of the data driver, the multi-level signals for converting the multi-level signals into the gray coded data; and
converting, at a second data processor of the data driver, the gray coded data into the binary coded data for converting the binary coded data into the analog data voltages.

19. The method of claim 18, further comprising:
receiving, at a receiving stage of the data receiver, the multi-level signals;
converting, at the receiving stage of the data receiver, the multi-level signals into the thermometer coded data; and
converting, at a demodulator of the data receiver, the thermometer coded data into the gray coded data.

20. The method of claim 14, wherein the multi-level signals have at least four levels.
